(19) United States
(12) Patent Application Publication
(10) Pub. No.: US 2008/0057220 A1
(43) Pub. Date: Mar. 6, 2008

(54) Silicon photovoltaic cell junction formed from thin film doping source

(76) Inventors: Robert Bachrach, Burlingame, CA (US); Tae Kyung Won, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 11/345,244

(22) Filed: Jan. 31, 2006

(51) Int. Cl. H05H 1/24; C23C 16/00

(52) U.S. Cl. 427/569; 427/248.1

(57) ABSTRACT

A method and apparatus for fabricating a solar cell and forming a p-n junction is disclosed. Solar cell p-n junction is formed by depositing a thin film of n-type phosphorus doped silicon material on a sheet from a mixture of precursors and annealing the sheet to obtain the p-n junction at a desired depth. In one embodiment, a plasma enhanced chemical vapor deposition chambers is used to deposit a phosphorus doped amorphous silicon film on a sheet surface by using precursors including a silicon-containing gas, a hydrogen-containing precursor, and a phosphorus-containing gas. In another embodiment, annealing furnace and/or rapid thermal processing chambers are used to anneal the sheet having the phosphorus doped amorphous silicon film deposited thereon.

### BACKGROUND OF THE INVENTION

1. Field of the Invention

Embodiments of the present invention generally relate to photovoltaic/solar cell and solar panel manufacturing.

2. Description of the Related Art

Photovoltaics (PV) systems can generate power for many uses, such as remote terrestrial applications, battery charging for navigational aids, telecommunication equipments, and consumer electronic devices, such as calculators, watches, radios, etc. One example of PV systems includes a stand-alone system which in general powers for direct use or with local storage. Another type of PV system is connected to conventional utility grid with the appropriate power conversion equipment to produce alternating current (AC) compatible with any conventional utility grid.

PV or solar cells are material junction devices which convert sunlight into direct current (DC) electrical power. When exposed to sunlight (consisting of energy from photons), the electric field of solar cell p-n junctions separates pairs of free electrons and holes, thus generating a photo-voltage. A circuit from n-side to p-side allows the flow of electrons when the solar cell is connected to an electrical load, while the area and other parameters of the PV cell junction device determine the available current. Electrical power is the product of the voltage times the current generated as the electrons and holes recombine.

Currently, solar cells and PV panels are manufactured by starting with many small silicon sheets or wafers as material units and processed into individual photovoltaic cells before they are assembled into PV module and solar panel. These silicon sheets are generally saw-cut p-type boron doped silicon sheets less than about 0.3 mm thick, precut to the sizes and dimensions that will be used, e.g., 10 cm×10 cm, 15.6 cm×15.6 cm, or 21 cm×21 cm. The cutting (sawing) or ribbon formation operation on the silicon sheets leaves damage to the surfaces of the precut silicon sheets, and etching processes, e.g., using alkaline or acid etching solutions, are performed on both surfaces of the silicon sheets to etch off about ten to twenty microns in thickness from each surface and provide surface textures thereon.

Junctions are then formed by diffusing an n-type dopant onto the precut p-type silicon sheets, generally performed by phosphorus diffusion as phosphorus is universally used as the n-type dopant for silicon in solar cells. One example to perform phosphorus diffusion includes coating phosphosilicate glass compounds onto the surface of the silicon sheets and carrying out diffusion/annealing inside a furnace. Another example of diffusing a phosphorus dopant to silicon includes bubbling nitrogen gas through liquid phosphorus oxychloride (POCl₃) sources which are injected into an enclosed quartz furnace loaded with batch-type quartz boats containing the silicon sheets. Typically, a high temperature is needed to form and create a p-n junction depth of about 0.1 microns up to about 0.5 microns. One or both surfaces of a PV cell can also be coated with suitable dielectrics after the p-n junction is formed. Dielectric layers are used to minimize surface charge carrier recombination and some dielectric materials, such as silicon dioxide, titanium dioxide, or silicon nitride, can be provided as antireflective coating to reduce reflection losses of photons.

The front or sun facing side of the PV cell is then covered with area minimized metallic contact grid for transporting current and minimizing current losses due to resistance through silicon-containing layers. Some blockage of sunlight or photons by the contact grid is unavoidable but can be minimized. The bottom of the PV cell is generally covered with a back metal which provides contact for good conduction as well as high reflectivity. Metal grids with patterns of conductive metal lines are used to collect current. Generally, screening printing thick-film technology is used in the PV cell industry to layer a conductive paste of metal materials, e.g., silver, etc., into a desired pattern and deposit a metal material layer to the surface of the silicon sheets or substrates for forming metal contact fingers or wiring channels. Other thin film technologies may be used for contact formation or electrode processing. The deposited metal layer, formed into contacts, is often fired or sintered at high temperature to form into good conductors in direct contact with underlying silicon materials, and a single PV cell is made.

To create a solar panel appropriately sized to deliver the needed amount of power output and wired to achieve the desired operating voltage and current, a number of individual PV cells are tiled together forming an array of cells. For example, several PV cells may be interconnected in series or parallel electrical circuits into a PV module. A number of PV modules can also be assembled into pre-wired panels or arrays. Interconnection wiring of each PV cell into strings or modules is performed by soldering and wiring metal tabs and auxiliary tabs together. Generally, metal tabs are soldered to bus bars on the surface of a PV cell to wire metal contacts or metal fingers on each PV cell, provide interconnect links between PV cells, and allow thermal expansion. Currently, various wiring/interconnect schemes can be used for contact patterning and current collection, such as schemes using both front and back side wiring, schemes using front side current collection but all the contacts are brought to the back side, and other wiring schemes.

PV modules or panels are then bonded to or sealed in protective laminates or encapsulating barriers, such as ethylene vinyl acetate (EVA) sheets, and covered with a front glass pane and a back pane, which are glass cover plates protecting the PV cells and providing structural re-enforcement. Protection of the active PV devices during module construction directly affects the performance and lifetime of the final PV systems. Regardless of size, a single PV cell generally produces about 0.5-0.6 volt DC current. A common configuration uses about 36 connected PV cells for a maximum of about 15 volts, compatible with major appliances and appropriate for 12 volts battery charging.

Optimized solar cells usually mean maximum power generated by solar cell junction devices at minimum cost. Although phosphorus diffusion of the phosphorus doped n-type silicon material for solar junction formation could be created by the furnace-type diffusion/annealing processes as discussed above, these processes require handling of gaseous diffusion processes and difficult gas sources and necessitate many additional pre-cleaning, post-cleaning, etching, and stripping steps. Often times, impurities are incorporated into the silicon sheets after phosphorus diffusion. For example, an amorphous layer of phosphorus silicate glass remained at the surface may need to be etched of, such as by wet chemical etching in diluted hydrofluoric acid (HF) solutions. In addition, after phosphorus diffusion, p-n junction isolation is often required to remove excess n-type regions at the edges of the silicon sheets by sand blasting, plasma etch, or laser cutting. Over all, these prior junction formation techniques are not economical for solar cell fabrication.

Therefore, there is a need for effective solar cell p-n junction formation to improve the fabrication process of solar cells.

### SUMMARY OF THE INVENTION

Aspects of the invention provide a method of forming n-type silicon thin films on a sheet suitable for solar cell junction formation without the need of additional cleaning or stripping steps. Solar cell p-n junction is formed by depositing a thin film of n-type phosphorus doped silicon material on a p-type silicon sheet or substrate from a mixture of precursors and annealing the sheet to obtain the p-n junction to a desired depth. In one embodiment, a plasma enhanced chemical vapor deposition chambers is used to deposit a phosphorus doped amorphous silicon film on a sheet surface by using precursors including a silicon-containing gas, a hydrogen-containing precursor, and a phosphorus-containing gas. In another embodiment, annealing furnace and/or rapid thermal processing chambers are used to anneal the sheet having the phosphorus doped amorphous silicon film deposited thereon.

In one aspect, a method is provided for forming a p-n junction on a silicon sheet. The method includes placing the silicon sheet having p-type silicon material thereon inside a vacuum deposition chamber, delivering a mixture of precursors comprising a silicon-containing compound and a phosphorus-containing compound into the vacuum deposition chamber, and depositing a phosphorus doped silicon film having a first thickness on the surface of the silicon sheet over the p-type silicon material at a first temperature. The method further includes annealing the silicon sheet at a second temperature greater than the first temperature to obtain the p-n junction to a desired depth and form the p-n junction on the silicon sheet.

In another aspect, a method for forming a p-n junction on a sheet includes placing the sheet having p-type silicon material thereon inside a vacuum deposition chamber, delivering a mixture of precursors comprising a silicon-containing compound, a hydrogen-containing compound, and a phosphorus-containing compound into the vacuum deposition chamber, depositing a n-type phosphorus doped amorphous silicon film having a thickness between about 50 nm and about 200 nm on the surface of the sheet over the p-type silicon material at a first temperature, and annealing the sheet at a second temperature greater than the first temperature to obtain the p-n junction to a desired depth and form the p-n junction on the sheet.

In still another aspect, an apparatus for fabricating a solar cell p-n junction on a sheet includes a chamber body, a sheet processing region adapted to processing one or more sheets having p-type silicon material thereon, one or more gas sources adapted to deliver a mixture of precursors comprising a silicon-containing compound, and a phosphorus-containing compound into the sheet processing region, a sheet support assembly, and a gas distribution assembly connected to one or more power sources adapted to sustain a plasma in the sheet processing region from the mixture of precursors and deposit a n-type phosphorus doped amorphous silicon film having a thickness between about 50 nm and about 200 nm on the surface of the sheet over the p-type silicon material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a process flow diagram illustrating an exemplary method incorporating one embodiment of the invention.

FIG. 2 is a schematic cross-sectional view of one embodiment of a process chamber in accordance with the invention.

FIG. 3 depicts cross-sectional schematic views of a sheet with a n-type doped silicon film deposited on top in accordance with one embodiment of the invention.

FIG. 4 depicts cross-sectional schematic views of prior art phosphorus diffusion of an n-type doped silicon material over the surfaces of a sheet.

### DETAILED DESCRIPTION

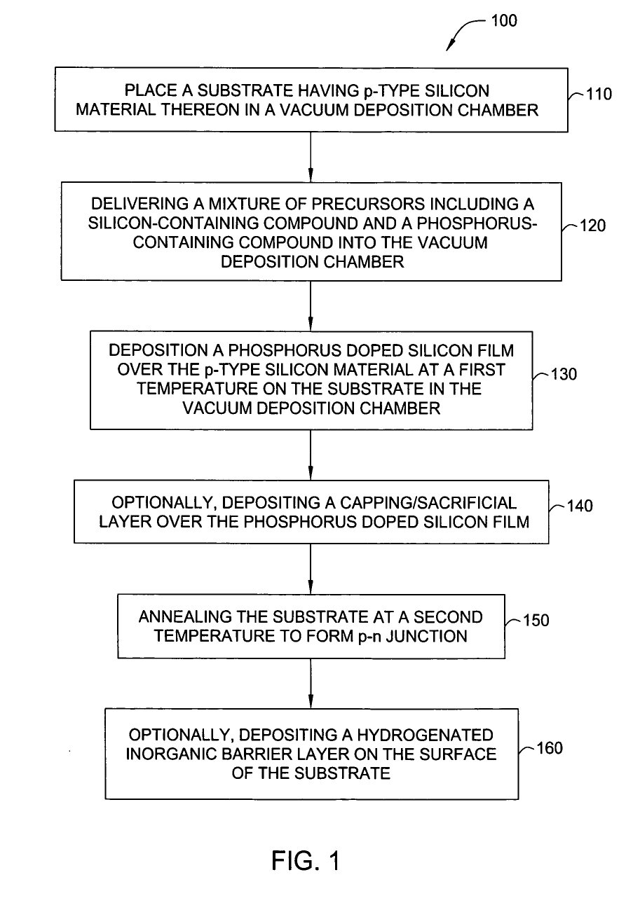

The present invention provides method and apparatus to deposit n-type phosphorus doped silicon thin films on a sheet. The deposited phosphorus doped silicon thin films can be used to form p-n junction after annealing the sheet at high temperatures. FIG. 1 depicts a process flow diagram illustrating one exemplary method 100 of the invention. At step 110, a sheet is placed in a vacuum deposition chamber. The vacuum deposition chamber can be a stand-alone chamber or as part of a sheet processing system. In some cases, the vacuum deposition chamber may be part of a multi-chamber system. The sheet of the invention can be any of the sheet types suitable for PV cell and solar module fabrication, e.g., monocrystalline silicon, polycrystalline silicon, amorphous silicon, silicon ribbon sheet, cadmium telluride, gallium arsenide, polymer, plastic, organic material, among others. The shape of the sheet can vary, e.g., single crystal silicon wafer shape, quasi-square form, etc., and the sheet is not limiting and can be any sheet or substrate comprised of silicon, polymer, composite, metal, plastic, wafer or glass materials.

In one embodiment, a sheet suitable for solar cell fabrication is used. A sheet size of about 50 mm×50 mm or larger can be used. Typical sheet size for solar cell fabrication may be about 100 mm×100 mm or larger, such as about 156 mm×156 mm or larger in size; however, smaller or lager sizes/dimensions can also be used to advantage, e.g., a size of about 400 mm×500 mm can also be used. The thickness of a solar cell sheet may, for example, be a few hundreds microns, such as between about 100 microns to about 350 microns. Each sheet may be suitable for forming a single p-n junction, a dual junction, a triple junction, tunnel junction, p-i-n junction, or any other types of p-n junctions created by suitable semiconductor materials for solar cell manufacturing. In another embodiment, at least a surface of the sheet may include p-type silicon material thereon.

At step 120, a mixture of precursors or source compounds are delivered into the vacuum deposition chamber for forming of phosphorus-doped silicon materials directly on a surface of the sheet. The mixture of precursors may include a silicon-containing compound and a phosphorus-containing compound.

The silicon-containing compound may include silane (SiH4), Si₂H₆, SiF₄, among others, for depositing a layer of n-type phosphorus-doped silicon film directly onto the sheet having the p-type silicon material thereon. The silicon-containing compound can be delivered, for example, at a flow rate of 10 sccm or larger, such as between about 100 sccm to about 500 sccm for a sheet size of about 50 mm×about 50 mm or larger. The phosphorus-containing compound may include phosphine (PH₃) and others, useful to dope a small amount of phosphorus into the n-type phosphorus-doped silicon film, and can be delivered at a flow rate of about 10 sccm or larger, such as between about 100 sccm to about 3000 sccm.

The mixture of precursors may further include a hydrogen-containing compound, including, but not limited to, hydrogen gas (H₂), ammonium (NH₃), and combinations thereof. The hydrogen-containing compound can be delivered at a flow rate of about 100 sccm or larger, such as between about 400 sccm to about 4000 sccm for various hydrogen-containing precursors. Additionally, a nitrogen-containing compound can be included in the mixture of precursors.

For example, a mixture of the precursors may include silane, hydrogen gas and phosphine, among others, for depositing a phosphorus-doped amorphous silicon film, such as a phosphorus-doped amorphous silicon film or a microcrystal silicon film. Each precursor can be delivered at different or the same flow rate, depending on various deposition parameters required. The inventors have found that, in one embodiment of the invention, a high flow rate of phosphine (PH₃) at about 2000 sccm or less, such as about 1200 sccm or less, is useful for depositing a phosphorus-doped amorphous silicon film with good surface properties. In addition, a low flow rate of the hydrogen gas is found to reduce the resistivity of the phosphorus-doped amorphous silicon film, such as from a measurement of about 1.0×10³ Ω-cm being reduced to about less than 100 Ω-cm, preferably about 10 Ω-cm or lower, most preferably about 1 Ω-cm or lower. Hydrogen gas can be used at a low flow rate of less than about 1000 sccm, such as about 800 sccm or less, e.g., at about 500 sccm, to improve the adhesion of a phosphorus-doped amorphous silicon film to the sheet surface, as compared to no hydrogen gas used.

At step 130, a phosphorus-doped silicon film having a first thickness is deposited onto a surface of the sheet at a first temperature in the vacuum deposition chamber. The first temperature may be between about 200° C. and about 400° C. for solar cell fabrication. The pressure inside the vacuum deposition chamber is not limiting and can be, for example, at a pressure of between about 0.5 Torr and about 5 Torr. The first thickness of the deposited phosphorus-doped silicon film may be controlled by the deposition time and required process parameters and may be about 50 nm or thicker, such as between about 50 nm and about 200 nm.

At step 140, a capping layer or sacrificial layer may be optionally deposited to protect the deposited phosphorus doped silicon film on the surface of the sheet. For example, a layer of silicon nitride or silicon oxide material may be deposited by the same or different vacuum deposition chamber, which may be within the same or different sheet processing system. In one example, a silicon nitride layer having a thickness of about 5 nm or larger, such as between about 20 nm and 500 nm, may be deposited from a mixture of a silicon-containing gas and one or more nitrogen-containing gases inside a chemical vapor deposition chamber at a deposition temperature of between about 200° C. and about 400° C. Hydrogen-containing gases, such as hydrogen gas (H₂), may also be included for depositing the capping/sacrificial layer to improve film surface properties. Silicon-containing gas, including silane (SiH4), Si₂H₆, SiF₄, among others, may be used. The one or more nitrogen-containing gases may include, but are not limited to, ammonium (NH₃), nitrous oxide (N₂O), nitric oxide (NO), nitrogen (N₂), and combinations thereof. The nitrogen-containing gas can be delivered at a flow rate of about 5 sccm or larger, such as between about 100 sccm to about 6000 sccm for various nitrogen-containing precursors. Not wishing to be bound by theory, it is believed that a capping layer or a passivating layer prevent the phosphorus dopant and other impurities and sources from escaping the surface of the sheet, especially during the later annealing process.

At step 150, p-n junction is formed by annealing the sheet at a second temperature higher than the first temperature. Not wishing to be bound by the theory, it is believed that annealing at high temperature re-crystallizes the phosphorus doped amorphous silicon film over the surface of the sheet such that a concentration gradient of the charge carriers (electrons) from the deposited n-type phosphorus-doped silicon film and a concentration gradient of the charge carriers (holes) from the sheet having the p-type silicon material are formed. The p-n junction formed therebetween may include a depth of about 100 nm to about 500 nm.

Annealing the sheet can be performed by an annealing process at a high temperature of about 800° C. or higher inside a furnace or, alternatively, by a rapid thermal annealing process at a high temperature of about 900° C. or higher inside a rapid thermal processing chamber. Furnace annealing may take longer time than rapid thermal annealing but it additionally provides metal gettering on the sheet, which is often needed during solar cell fabrication. On the other hand, annealing the sheet inside a rapid thermal processing chamber may save processing time and may require a high quality sheet having better, purer starting materials thereon. The annealing furnaces or rapid thermal processing chambers are readily available, such as those available from Applied Materials, Inc., Santa Clara, Calif. For example, annealing can be performed in a Vantage Radiance processing system, available from Applied Materials, Inc., Santa Clara, Calif.

After annealing and solar cell junction is formed, the sheet may be subjected to a variety of wiring schemes and/or surface treatment steps. In one embodiment, the capping/sacrificial layer may need to be removed before proceeding to next processing steps. For example, a deposited silicon nitride capping layer may be stripped away and the surface of the sheet may be cleaned, such as by wet chemical etching in a diluted hydrofluoric acid (HF) solution. Stripping the deposited capping layer may be performed by standard wet or dry chemistries, such as using a phosphoric acid at high temperature, e.g., at around 175° C.

Optionally, at step 160, a hydrogenated inorganic barrier layer is deposited on the surface of the sheet. Hydrogenation is important for solar cell fabrication since atomic hydrogen may interact with impurities and defects inside the sheet, neutralize recombination properties. For example, a hydrogenated amorphous silicon nitride layer (a-SiNₓ:H) can be deposited to a thickness of about 5 nm or larger, such as about 70 nm at a deposition temperature of between about 200° C. and about 400° C., after the p-n junction is formed on the sheet to serve as a barrier/passivation layer as well as an anti-reflective coating layer. Other suitable hydrogenated inorganic barrier materials, such as silicon dioxide, titanium dioxide, among others, can also be deposited. In one embodiment, a hydrogenated amorphous silicon nitride layer is deposited inside a plasma enhanced chemical vapor deposition chamber using precursors including a silicon-containing gas, one or more nitrogen-containing gases, and hydrogen gas (H₂), resulting in up to 40 atomic % of hydrogen, such as between 5 atomic % and 30 atomic % of hydrogen.

In one embodiment, the steps of the method 100 may need to be repeated such that one or both surfaces of the sheet are processed by the method 100 of the invention to form p-n junction on the sheet. The deposition and annealing processes as described in the method 100 of the invention result in more effective junction formation and eliminate gaseous diffusion steps, difficult gas sources and liquid sources, or any complex clean up steps which are required before and after sheet processing, as compared to prior art phosphorus diffusion processes.

Accordingly, in one embodiment, the invention includes a process for forming a p-n junction of a solar cell by depositing a thin film of n-type phosphorus doped amorphous silicon material on the sheet from a mixture of precursors and annealing the sheet to obtain the p-n junction at a desired depth. In another embodiment, a phosphorus doped amorphous silicon film is deposited on a sheet surface by plasma enhanced chemical vapor deposition using precursors including a silicon-containing gas, a hydrogen-containing precursor, and a phosphorus-containing gas.

Suitable vacuum deposition chamber may include various chemical vapor deposition chambers. The invention is illustratively described below in reference to a plasma enhanced chemical vapor deposition system configured to process various types of sheets, such as various parallel-plate radio-frequency (RF) plasma enhanced chemical vapor deposition (PECVD) systems for various sheet sizes, available from AKT, a division of Applied Materials, Inc., Santa Clara, Calif. However, it should be understood that the invention has utility in other system configurations, such as other chemical vapor deposition systems and any other film deposition systems.

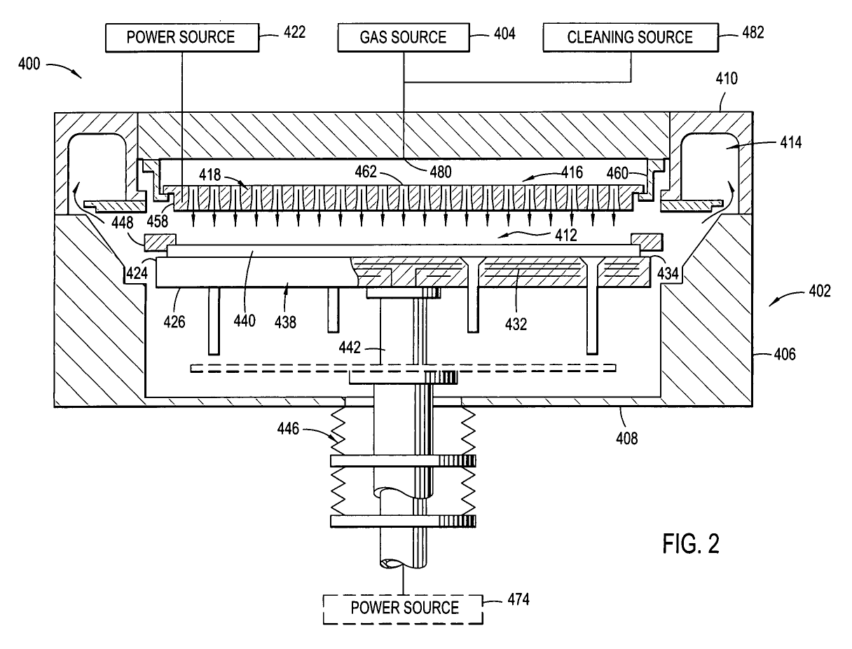

FIG. 2 is a schematic cross-sectional view of one embodiment of a plasma enhanced chemical vapor deposition system 400 having one or more plasma enhanced chemical vapor deposition chambers, available from AKT, a division of Applied Materials, Inc., Santa Clara, Calif. The sheet processing system 400 generally includes one or more processing chambers 402, sheet input/output chambers, a main transfer robot for transferring sheet among the sheet input/output chambers and the processing chambers 402, and a mainframe controller for automatic sheet processing control.

The processing chamber 402 is usually coupled to one or more supply sources 404 for delivery one or more source compounds and/or precursors. The one or more supply sources 404 may include a silicon-containing compound supply source, a phosphorus-containing compound supply source, a hydrogen gas supply source, a nitrogen-containing compound supply source, among others. The processing chamber 402 has walls 406 and a bottom 408 that partially define a process volume 412. The process volume 412 is typically accessed through a port and a valve (not shown) to facilitate movement of a sheet 440, such as a solar cell glass sheet, into and out of the processing chamber 402. The walls 406 support a lid assembly 410 that contains a pumping plenum 414 that couples the process volume 412 to an exhaust port (that includes various pumping components, not shown) for exhausting any gases and process by-products out of the processing chamber 402.

A sheet support assembly 438 is centrally disposed within the processing chamber 402. The sheet support assembly 438 supports the sheet 440 during processing and its temperature can be controlled. The sheet support assembly 438 comprises an aluminum body 424 that encapsulates at least one embedded heater 432. The heater 432, such as a resistive element, disposed in the sheet support assembly 438, is coupled to an optional power source 474 and controllably heats the support assembly 438 and the sheet 440 positioned thereon to a predetermined temperature. In one embodiment, the temperature of the heater 432 can be set at about 200° C. or higher, such as between about 200° C. to about 400° C., depending on the deposition processing parameters for the conditioning material being deposited. In another embodiment, a port having hot water flowing therein is disposed in the sheet support assembly 438 to maintain the sheet 440 at a uniform temperature of 200° C. or higher.

The sheet support assembly 438 generally is grounded such that RF power supplied by a power source 422 to a gas distribution plate assembly 418 positioned between the lid assembly 410 and sheet support assembly 438 (or other electrode positioned within or near the lid assembly of the chamber) may excite gases present in the process volume 412 between the support assembly 438 and the gas distribution plate assembly 418. The RF power from the power source 422 is generally selected commensurate with the size of the sheet to drive the chemical vapor deposition process.

In one embodiment, a RF power of about 10 W or larger, such as between about 100 W to about 5000 W, is applied to the power source 422 to generate an electric field in the process volume 412. For example, a power density of about 0.2 watts/cm2 or larger, such as between about 0.2 watts/cm² to about 0.8 watt/cm², or about 0.45 watts/cm², can be used to be compatible with the sheet deposition method of the invention. The power source 422 and matching network (not shown) create and sustain a plasma of the process gases from the precursor gases in the process volume 412. Preferably high frequency RF power of 13.56 MHz can be used, but this is not critical and other frequencies can also be used. Further, the walls of the chamber can be protected by covering with a ceramic material or anodized aluminum material.

Generally, the sheet support assembly 438 has a lower side 426 and an upper side 434, supporting the sheet 440. The lower side 426 has a stem 442 coupled thereto and connected to a lift system (not shown) for moving the support assembly 438 between an elevated processing position (as shown) and a lowered sheet transfer position. The stem 442 additionally provides a conduit for electrical and thermocouple leads between the sheet support assembly 438 and other components of the system 400. A bellows 446 is coupled to the sheet support assembly 438 to provide a vacuum seal between the process volume 412 and the atmosphere outside the processing chamber 402 and facilitate vertical movement of the sheet support assembly 438.

In one embodiment, the lift system is adjusted such that a spacing between the sheet and the gas distribution plate assembly 418 is about 400 mils or larger, such as between about 400 mils to about 1600 mils, e.g., about 900 mils, during processing. The ability to adjust the spacing enables the process to be optimized over a wide range of deposition conditions, while maintaining the required film uniformity over the area of a large sheet. The combination of a grounded sheet support assembly, a ceramic liner, high pressures and close spacing gives a high degree of plasma confinement between the gas distribution plate assembly 418 and the sheet support assembly 438, thereby increasing the concentration of reactive species and the deposition rate of the subject thin films.

The sheet support assembly 438 additionally supports a circumscribing shadow frame 448. Generally, the shadow frame 448 prevents deposition at the edge of the sheet 440 and support assembly 438 so that the sheet does not stick to the support assembly 438. The lid assembly 410 typically includes an entry port 480 through which process gases provided by the gas source 404 are introduced into the processing chamber 402. The entry port 480 is also coupled to a cleaning source 482. The cleaning source 482 typically provides a cleaning agent, such as disassociated fluorine, that is introduced into the processing chamber 402 to remove deposition by-products and films from processing chamber hardware, including the gas distribution plate assembly 418.

The gas distribution plate assembly 418 is typically configured to substantially follow the profile of the sheet 440, for example, square or polygonal for large area sheets and circular for wafers. The gas distribution plate assembly 418 includes a perforated area 416 through which precursors and other gases, such as hydrogen gas, silane, phosphine, supplied from the gas source 404 are delivered to the process volume 412. The perforated area 416 is configured to provide uniform distribution of gases passing through the gas distribution plate assembly 418 into the processing chamber 402. The gas distribution plate assembly 418 typically includes a diffuser plate 458 suspended from a hanger plate 460. A plurality of gas passages 462 are formed through the diffuser plate 458 to allow a predetermined distribution of gas passing through the gas distribution plate assembly 418 and into the process volume 412.

Gas distribution plates that may be adapted to benefit from the invention are described in commonly assigned U.S. patent application Ser. Nos. 09/922,219, filed Aug. 8, 2001 by Keller et al.; 10/140,324, filed May 6, 2002; and 10/337,483, filed Jan. 7, 2003 by Blonigan et al.; U.S. Pat. No. 6,477,980, issued Nov. 12, 2002 to White et al.; and U.S. patent application Ser. No. 10/417,592, filed Apr. 16, 2003 by Choi et al., which are hereby incorporated by reference in their entireties.

According to one method of the invention, a sheet having p-type silicon material thereon is placed in a deposition process chamber. A mixture of precursors for depositing a thin film of n-type phosphorus doped amorphous silicon is delivered into the process chamber. In one embodiment, the thin film is deposited using precursors including combinations of one or more of a silicon-containing gas, a nitrogen-containing gas, a phosphorus-containing gas, and a hydrogen-containing gas.

The n-type phosphorus doped amorphous silicon film is deposited onto the sheet by applying an electric field and generating a plasma inside the deposition process chamber. The electric field can be generated by applying a power source, such as radio-frequency power or microwave frequency power, to the deposition process chamber. The power source can be coupled to the deposition process chamber inductively or capacitively. The power used can be varied, depending on what type of the film is deposited and the surface area of the sheet and the support assembly. In general, a power of between about 100 W to about 1500 W can be used in a system having a sheet receiving surface area of about 2000 cm² or less.

A sheet temperature of about 200° C. or higher, such as between about 250° C. to about 350° C., e.g., at about 300° C., is used. The pressure of the process chamber is maintained at about 0.5 Torr to about 10 Torr, such as at about 0.5 Torr to about 2.5 Torr. The n-type phosphorus doped amorphous silicon film is deposited at a deposition rate of about 100 Å/min or higher, such as about 500 Å/min or higher, or in some cases, about 1000 Å/min or higher, e.g., between about 800 Å/min to about 1500 Å/min.

After the n-type phosphorus doped amorphous silicon film is deposited over the sheet, annealing at high temperature, such as at a temperature of about 1000° C., is performed inside a furnace, such as those available from Tokyo Electronic Limited, in order to diffuse the phosphorus dopant into the silicon materials in the sheet and form p-n junction. Alternatively, rapid thermal annealing chamber, such as those available from Applied Material Inc., can also be used to anneal the sheet.

As an example, for solar cell fabrication, additional layers can be deposited on the sheet. For example, one or more passivation layer or anti-reflective coating layer can be deposited on the front and/or back side of the sheet. In addition, a plurality of features can then be patterned on the sheet using any of suitable patterning techniques, including, but not limited to, dry etch, wet etch, laser drilling, chemical mechanical jet etch, and combinations thereof. Suitable features include vias, contacts, contact windows, trenches, among others. Various antireflective coating materials can be used, including various dielectric materials, such as silicon nitride, titanium oxide, amorphous carbon material, etc., suitable for use in PV cells exposed to the solar flux. The absorption coefficient of the antireflective coating materials should be minimized but can vary. In one example, a silicon nitride layer at a thickness of about 70 nm to about 80 nm can be deposited to the front and back side of the sheet as well as to the via walls and provide as a barrier layer, encapsulating layer, and/or antireflective coating. Optionally, additional layers of anti-reflection coating can be deposit for better index matching, such as a second front side dielectric antireflective coating layer. Contacts, such as electrodes, contact windows, wiring channels, among others, are formed on the front and/or back side of the sheet such that suitable semiconductor contact can be formed by well established semiconductor processing methods. Further, current collection wirings can be formed on the front or back side of the sheet using suitable wiring metallization technique. Silver is commonly used, but aluminum or copper wiring has cost and performance advantages and can be readily incorporated into the process herein described.

Additional metallization and film deposition required for fabricating different types of solar cell can be performed, depending on different applications used for laboratorial or industrial uses. Various types of PV cells may be desired to manufacture into a solar panel, including, Passivated Emitter Rear Locally diffused (PERL) cell, thin film silicon cell, Passivated Emitter Rear Totally diffused (PERT) cell, Zone-Melting Recrystallization (ZMR) cell, Surface Texture and enhanced Absorption with a back Reflector (STAR) cell, among others. For example, in some cases, metallization processing on the back side of the sheet may be optionally performed to deposit high reflectivity materials. Then, the sheet is ready to be manufactured into a solar module or panel. For example, one or more sheets that have been processed by one or more steps of the invention as described above may be arranged on a wiring backplane for fabricating into a solar module/panel, such as by tiling up a number of the sheets of the invention on the wiring plane. The wiring plane can be any of the insulating wiring back planes suitable for PV module manufacturing, such as a metal foil or a thick metal film on a plastic film with suitable insulating and barrier properties. In addition, the wiring backplane may include appropriate conductor patterns thereon for conducting current between PV cells with minimal resistivity loss. The backplane conductor patterns are designed to match with the virtual design of the wiring scheme for the sheet of the invention and individual PV cell. Forming or patterning a layer of a metal conductor on the wiring backplane creates the needed wiring. The wiring pattern reflects the needed connections for each of the final soalr cell. The wiring conductor patterns can be any of the suitable series-parallel organization (interconnection), depending on the design and intended use of the final solar panel to achieve the specified operative voltage and current. Bonding of the one or more sheets to the wiring plane can be perform by suitable techniques, including, not limited to, soldering with or without lead, epoxy, thermal annealing, ultrasonic annealing, among others. Then, the solar panel assembly can be bonded to additional protective films. One exemplary protective film is DuPont™ Tedlar® PVF (poly-vinyl fluoride). Protective films can be bonded to the back side of the wiring backplane to protect the conductor patterns and electrical output leads thereon from environmental corrosion or other damages while lightening the overall structure.

### EXAMPLES

Sheets were brought under vacuum inside a plasma enhanced chemical vapor deposition (PECVD) system, available from Applied Materials, Inc., Santa Clara, Calif., with a spacing of about 900 mils to about 1000 mils. The temperature of the sheet support (susceptor) was set at about 350° C. for a low temperature deposition process.

Mixtures of silane (SiH₄), phosphine (PH₃), in the presence of hydrogen gas (H₂) were delivered into the chamber as the source precursor gases for depositing a phosphorus-doped amorphous silicon film onto the sheet having p-type silicon material thereon. The pressure inside the chamber is about 0.7 Torr. A plasma was sustained with RF power generator set at about 13.56 MHz and about 250 W. The results showed that the deposited phosphorus doped amorphous silicon film exhibits good step coverage, good uniformity of about 10% or higher over the surface of the sheet (e.g., an uniformity of 70 nm to 90 nm at an average thickness of about 80 nm Å), and good surface properties with good adhesion to the surface of the sheet. Good step coverage is especially desirable when the starting sheet having the p-type silicon material thereon includes a textured surface.

Annealing of the sheet having the deposited phosphorus doped amorphous silicon film is performed inside a Vantage sheet processing system, available from Applied Materials, Inc., Santa Clara, Calif. at a temperature of about 900° C. and p-n junction is formed on the sheet.

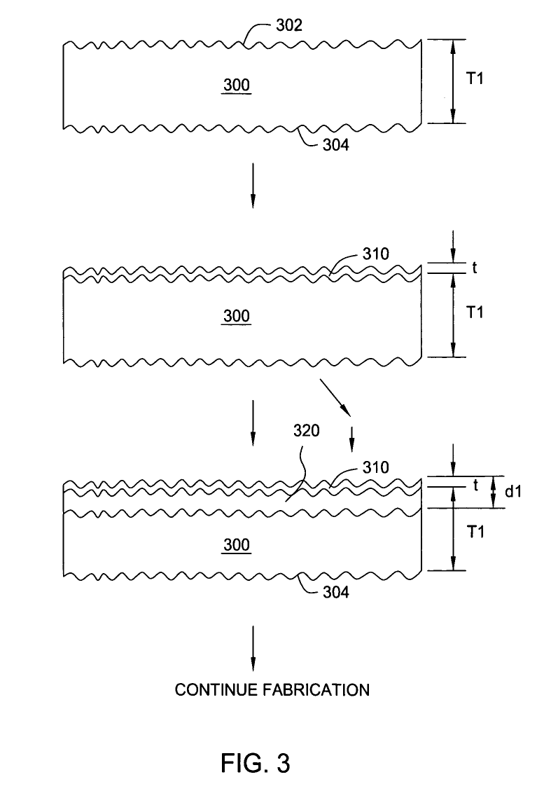

FIG. 3 depicts exemplary cross-sectional schematic views of forming a p-n junction on a sheet 300 in accordance with one embodiment of the invention. The sheet 300 having a thickness of T1 may include p-type silicon materials therein. For solar cell fabrication, one or more surfaces 302, 304 of the sheet 300 may be textured to assist in light-trapping or light-confinement, and reduce reflection loss. A thin film of n-type phosphorus doped amorphous silicon 310 is then deposited to a first thickness, t, according to the method of the invention. The first thickness, t, of the deposited n-type phosphorus doped amorphous silicon may be about 10 nm or more, such as in the range of about 50 nm to about 200 nm. Good step coverage can be obtained after deposition of the n-type phosphorus doped amorphous silicon 310, for example, by a plasma enhanced chemical vapor deposition technique as described herein. Next, p-n junction 320 is formed between the deposited n-type phosphorus doped amorphous silicon 310 and the sheet 300 after annealing the sheet 300 at high temperature. The p-n junction 320 may include a depth, d1, which may be for example, in the range of about 100 nm to about 500 nm. After the p-n junction is formed, fabrication can be continued. For example, anti-reflective coating materials, metal layers, and/or other dielectric layers can be deposited on the surfaces of the sheet 300.

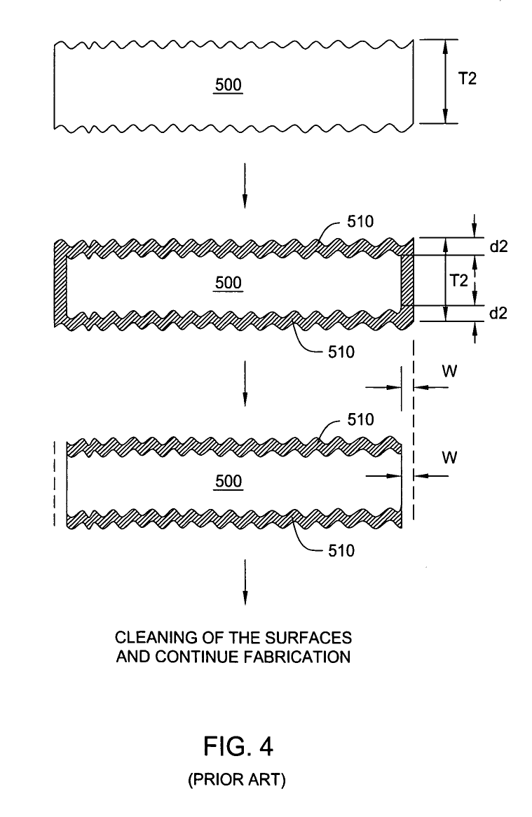

As a comparison, phosphorus diffusion was used to create p-n junction on a p-type boron doped silicon sheet sheet. FIG. 4 depicts cross-sectional schematic views of prior art annealing/diffusion of phosphorus dopant over the surfaces of a sheet 500 containing p-type silicon material. The prior art phosphorus diffusion technique directly diffuses phosphorus dopant into the sheet 500 to form solar cell p-n junction having a n-type region 510 without the formation of any thin film. The n-type region 510 contains silicon materials doped with phosphorus which is diffused into the surfaces of the sheet in a phosphorus concentration gradient to a depth, d2. The n-type region 510 formed by phosphorus diffusion can cover the top, the bottom, and the edges of the sheet 400. Thus, the junction was typically isolated around the edges by etching off a width, w, near the n-type region on the edges of the sheet 500. Cleaning of the surfaces of the sheet after phosphorus diffusion may be additionally required before fabrication is continued and additional layers are formed on the surfaces of the sheet 500.

Although the invention has been described in accordance with certain embodiments and examples, the invention is not meant to be limited thereto. The CVD process herein can be carried out using other CVD chambers, adjusting the gas flow rates, pressure, plasma density, and temperature so as to obtain high quality films at practical deposition rates. It is understood that embodiments of the invention include scaling up or scaling down any of the process parameter/variables as described herein according to sheet sizes, chamber conditions, etc., among others.

While the foregoing is directed to embodiments of the present invention, other and further embodiments of the invention may be devised without departing from the basic scope thereof, and the scope thereof is determined by the claims that follow.

1. A method for forming a p-n junction on a silicon sheet, comprising:
placing the silicon sheet having p-type silicon material thereon inside a vacuum deposition chamber;
delivering a mixture of precursors comprising a silicon-containing compound and a phosphorus-containing compound into the vacuum deposition chamber;
depositing a phosphorus doped silicon film having a first thickness on the surface of the silicon sheet over the p-type silicon material at a first temperature; and
annealing the silicon sheet at a second temperature greater than the first temperature to obtain the p-n junction to a desired depth and form the p-n junction on the silicon sheet.

2. The method of claim 1, wherein the silicon-containing compound comprises comprises a compound selected from the group consisting of silane, SiF₄, Si₂H₆, and combinations thereof.

3. The method of claim 1, wherein the mixture of precursors further comprises hydrogen gas (H₂).

4. The method of claim 1, wherein the mixture of precursors comprises silane, hydrogen gas, and phosphine.

5. The method of claim 1, wherein the phosphorus doped silicon film comprises a n-type phosphorus doped amorphous silicon material.

6. The method of claim 1, wherein the vacuum deposition chamber is a plasma enhanced chemical vapor deposition chamber (PECVD).

7. The method of claim 1, wherein annealing is performed inside an annealing furnace.

8. The method of claim 1, annealing is performed inside a rapid thermal processing chamber.

9. The method of claim 1, further comprising forming a capping layer over the phosphorus doped silicon film.

10. The method of claim 9, wherein the capping layer comprises a silicon nitride material.

11. The method of claim 9, wherein the capping layer is formed by plasma enhanced chemical vapor deposition.

12. The method of claim 9, further comprising stripping the capping layer.

13. The method of claim 1, further comprising depositing a hydrogenated inorganic barrier layer on the surface of the silicon sheet.

14. The method of claim 13, wherein the hydrogenated inorganic barrier layer comprises a silicon nitride material.

15. The method of claim 13, wherein the hydrogenated inorganic barrier layer comprises between 5 atomic % and 30 atomic % of hydrogen.

16. A method for forming a p-n junction on a sheet, comprising:
placing the sheet having p-type silicon material thereon inside a vacuum deposition chamber;
delivering a mixture of precursors comprising a silicon-containing compound, a hydrogen-containing compound, and a phosphorus-containing compound into the vacuum deposition chamber;
depositing a n-type phosphorus doped amorphous silicon film having a thickness between about 50 nm and about 200 nm on the surface of the sheet over the p-type silicon material at a first temperature; and
annealing the sheet at a second temperature greater than the first temperature to obtain the p-n junction to a desired depth and form the p-n junction on the sheet.

17. The method of claim 16, wherein annealing is performed inside an annealing furnace.

18. The method of claim 16, annealing is performed inside a rapid thermal processing chamber.

19. The method of claim 16, wherein the vacuum deposition chamber is a plasma enhanced chemical vapor deposition chamber (PECVD).

20. A method for forming a p-n junction on a sheet, comprising:
placing the sheet having p-type silicon material thereon inside a vacuum deposition chamber;
delivering a mixture of precursors comprising a silicon-containing compound and a phosphorus-containing compound into the vacuum deposition chamber;
depositing a n-type phosphorus doped amorphous silicon film having a first thickness on the surface of the sheet over the p-type silicon material at a first temperature;
forming a capping layer over the n-type phosphorus doped amorphous silicon film;
annealing the sheet at a second temperature greater than the first temperature to obtain the p-n junction to a desired depth and form the p-n junction on the sheet; and
removing the capping layer from the surface of the sheet.

21. The method of claim 20, further comprising depositing a hydrogenated inorganic barrier layer on the surface of the sheet.
